(19) United States
(12) Patent Application Publication
(10) Pub. No.: US 2025/0216448 A1
(43) Pub. Date: Jul. 3, 2025

(54) SEMICONDUCTOR TEST APPARATUS

(71) Applicant: Samsung Electronics Co., Ltd., Suwon-si (KR)

(72) Inventors: Dongyoung LEE, Suwon-si (KR); Doyeon KIM, Suwon-si (KR); Sungok KIM, Suwon-si (KR); Jaeyoon SEOL, Suwon-si (KR); Hyowon CHOI, Suwon-si (KR)

(73) Assignee: Samsung Electronics Co., Ltd., Suwon-si (KR)

(21) Appl. No.: 18/948,664

(22) Filed: Nov. 15, 2024

(30) Foreign Application Priority Data
Dec. 27, 2023 (KR) 10-2023-0193181

(51) Int. Cl. G01R 31/28

(52) U.S. Cl. CPC G01R 31/2893; G01R 31/2894

(57) ABSTRACT

A semiconductor test apparatus includes a tray housing including a loading stacker, a first unloading stacker, and a second unloading stacker, the loading stacker configured to receive a plurality of semiconductor chips for testing, the first unloading stacker configured to receive any defective semiconductor chip among the plurality of semiconductor chips, and the second unloading stacker configured to receive any good semiconductor chip among the plurality of semiconductor chips, a loader configured to place, on a loading set plate, the plurality of semiconductor chips for testing, and load the plurality of semiconductor chips for testing onto a test tray, and a test device configured to test the plurality of semiconductor chips for testing stacked on the test tray.

### CROSS-REFERENCE TO RELATED APPLICATION

This U.S. non-provisional application is based on and claims the benefit of priority under 35 U.S.C. § 119 to Korean Patent Application No. 10-2023-0193181, filed on Dec. 27, 2023, in the Korean Intellectual Property Office, the disclosure of which is incorporated by reference herein in its entirety.

### BACKGROUND

Various example embodiments of the inventive concepts relate to a semiconductor test apparatus and/or a method of operating the semiconductor test apparatus, etc., and more particularly, to a semiconductor test apparatus capable of sorting semiconductor chips into defective products and good products, and/or a method of operating the same.

A semiconductor test process includes examining the electrical characteristics of semiconductor chips manufactured through semiconductor manufacturing processes, and classifying the semiconductor chips into good (e.g., acceptable, saleable, etc.) semiconductor chips and defective semiconductor chips according to the test results. According to the result of the semiconductor test process, only the semiconductor chips that are finally determined to be of good quality are provided to users. Regarding the semiconductor chips sorted as defective ones based on the test results, the semiconductor test apparatus makes a final determination that the semiconductor chips are faulty when the defects originate from faults in the semiconductor chips.

### SUMMARY

Various example embodiments of the inventive concepts provide a semiconductor test apparatus capable of testing semiconductor chips and classifying the semiconductor chips into good semiconductor chips and defective semiconductor chips, and/or a method of operating the semiconductor test apparatus, etc.

Technical problems to be solved by one or more of the example embodiments of the inventive concepts are not limited to the above description, and other technical problems may be clearly understood by one of ordinary skill in the art from the descriptions provided hereinafter.

According to at least one example embodiment of the inventive concepts, there is provided a semiconductor test apparatus including a tray housing including a loading stacker, a first unloading stacker, and a second unloading stacker, the loading stacker configured to receive a plurality of semiconductor chips for testing, the first unloading stacker configured to receive any defective semiconductor chip among the plurality of semiconductor chips, and the second unloading stacker configured to receive any good semiconductor chip of the plurality of semiconductor chips, a loader configured to place, on a loading set plate, the plurality of semiconductor chips for testing, and load the plurality of semiconductor chips for testing onto a test tray, a test device configured to test the plurality of semiconductor chips for testing stacked on the test tray, an unloader configured to classify the plurality of tested semiconductor chips into the defective any semiconductor chip and the any good semiconductor chip based on results of the testing, place the any defective semiconductor chip on the first unloading stacker, and place the any good semiconductor chip onto the second unloading stacker, and processing circuitry configured to, cause at least one robot to transfer the any defective semiconductor chip from the first unloading stacker to the loading set plate, cause the at least one robot to provide at least one additional semiconductor chip to the loading stacker, and instruct the test device to retest the any defective semiconductor chip.

According to at least one example embodiment of the inventive concepts, there is provided a semiconductor test apparatus including a tray housing including a first loading stacker and a second loading stacker, the first loading stacker configured to receive a first lot of semiconductor chips, and the second loading stacker configured to receive a second lot of semiconductor chips, a loader configured to transfer the first lot from the tray housing to a loading set plate, and transfer the first lot from the loading set plate to a test tray, a test device configured to test the semiconductor chips of the first lot on the test tray, an unloader configured to classify the semiconductor chips of the first lot into any defective semiconductor chip among the semiconductor chips of the first lot and any good semiconductor chip among the semiconductor chips of the first lot based on results of the testing, transfer the any defective semiconductor chip to a first unloading set plate, and transfer the any good semiconductor chip to a second unloading set plate, and processing circuitry configured to, cause at least one robot to transfer the any defective semiconductor chip from the first unloading set plate to the loading set plate, cause the at least one robot to transfer the any good semiconductor chip from the second unloading set plate to an unloading stacker, cause the at least one robot to transfer an additional lot to the first loading stacker, and instruct the test device to retest the any defective semiconductor chip on the loading set plate.

According to at least one example embodiment of the inventive concepts, there is provided a semiconductor test apparatus including a tray housing including a first loading stacker, a second loading stacker, a first unloading stacker, and a second unloading stacker, the first loading stacker configured to receive a first lot of semiconductor chips, the second loading stacker configured to receive a second lot of semiconductor chips, the first unloading stacker configured to receive any defective semiconductor chip among the first lot, and the second unloading stacker configured to receive any good semiconductor chip among the first lot, a loader configured to transfer the first lot from the tray housing to a test tray, a test device including a soak chamber, a test chamber, and a desoak chamber, the soak chamber configured to preheat the first lot, the test chamber configured to conduct a test on each of the semiconductor chips of the first lot, and the desoak chamber configured to change a temperature of the tested semiconductor chips of the first lot to room temperature, an unloader configured to classify the semiconductors of the first lot into the any defective semiconductor chip and the any good semiconductor chip based on results of the testing, transfer the any defective semiconductor chip to the first unloading stacker, and transfer the any good semiconductor chip to the second unloading stacker, and processing circuitry configured to, cause at least one robot to transfer the any defective semiconductor chip to a loading set plate without passing through the loading stacker, cause the at least one robot to transfer an additional semiconductor chip to the loading stacker, and instruct the test device to retest the any defective semiconductor chip.

### BRIEF DESCRIPTION OF THE DRAWINGS

Various example embodiments will be more clearly understood from the following detailed description taken in conjunction with the accompanying drawings in which:

FIG. 1 is a block diagram of a semiconductor test apparatus according to at least one example embodiment;

FIG. 2 is a flowchart illustrating the operation of a retest controller, according to at least one example embodiment;

FIG. 3 is a flowchart illustrating a semiconductor test method using a semiconductor test apparatus, according to at least one example embodiment;

FIG. 4 is a flowchart illustrating a semiconductor test method using a semiconductor test apparatus, according to at least one example embodiment;

FIG. 5 is a flowchart illustrating a semiconductor test method using a semiconductor test apparatus, according to at least one example embodiment;

FIG. 6 is a flowchart illustrating a semiconductor test method using a semiconductor test apparatus, according to at least one example embodiment;

FIG. 7 is a flowchart illustrating a semiconductor test method using a semiconductor test apparatus, according to at least one example embodiment;

FIG. 8 is a block diagram of a semiconductor test apparatus according to at least one example embodiment; and

FIG. 9 is a flowchart illustrating the operation of a retest controller, according to at least one example embodiment.

### DETAILED DESCRIPTION

Hereinafter, various example embodiments are described in detail with reference to the attached drawings. However, the example embodiments of the inventive concepts should not be limited to the example embodiments described below and may be realized in many different forms. The example embodiments described below are not provided to limit the inventive concepts, but rather provided to fully convey the scope of the inventive concepts to one of ordinary skill in the art.

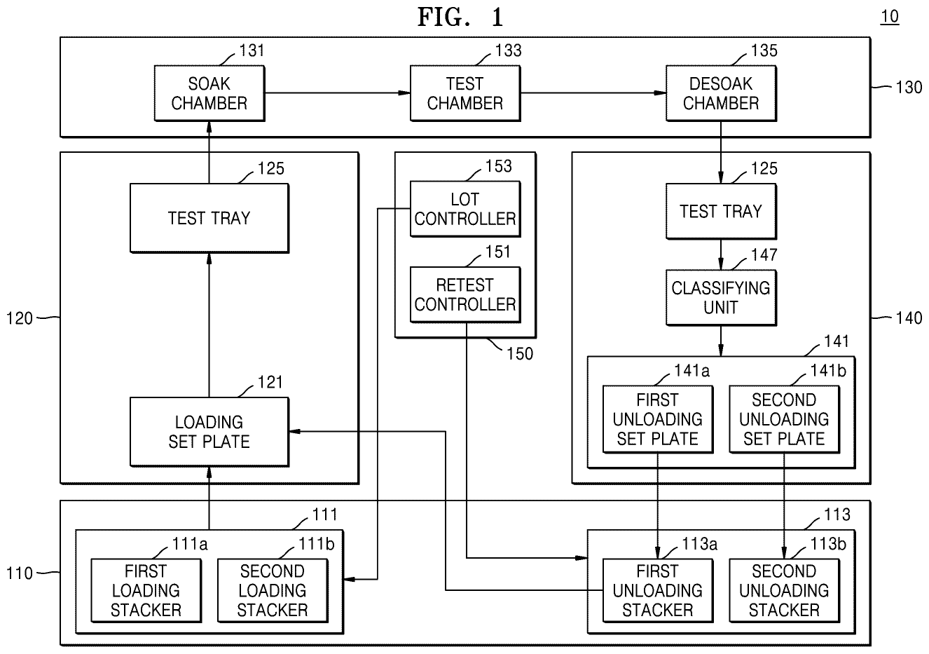

FIG. 1 is a block diagram of a semiconductor test apparatus 10 according to at least one example embodiment.

Referring to FIG. 1, the semiconductor test apparatus 10 may include a tray housing unit 110 (e.g., a tray housing, a tray housing device, etc.), a loading unit 120 (e.g., a loader, a loading device, etc.), a test unit 130 (e.g., a tester, a testing device, etc.), an unloading unit 140 (e.g., an unloader, an unloading device, etc.), and/or a controller 150 (e.g., control circuitry, processing circuitry, etc.), but the example embodiments are not limited thereto, and for example, the semiconductor test apparatus 10 may include a greater or lesser number of constituent components. According to some example embodiments, one or more of the test unit 130, the controller 150, etc., may be implemented as processing circuitry. Processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

The tray housing unit 110 may include a loading stacker 111 and/or an unloading stacker 113, etc. The loading stacker 111 may include a first loading stacker 111a and/or a second loading stacker 111b, and the unloading stacker 113 may include a first unloading stacker 113a and/or a second unloading stacker 113b, etc., but are not limited thereto. While FIG. 1 illustrates two loading stackers and two unloading stackers, the example embodiments are not limited thereto, and for example, there may be a greater or lesser number of loading stackers and/or unloading stackers included in the tray housing unit 110.

A customer tray, on which one or more semiconductor chips that have not yet been tested are stacked and/or may be accommodated in the first loading stacker 111a and the second loading stacker 111b, etc. In the first unloading stacker 113a, a customer tray on which semiconductor chips classified as defective products based on the test result are stacked and/or may be accommodated, and in the second unloading stacker 113b, a customer tray on which semiconductor chips classified as good products (e.g., defect-free products, acceptable products, functioning products, saleable products, etc.) based on the test result are stacked may be accommodated.

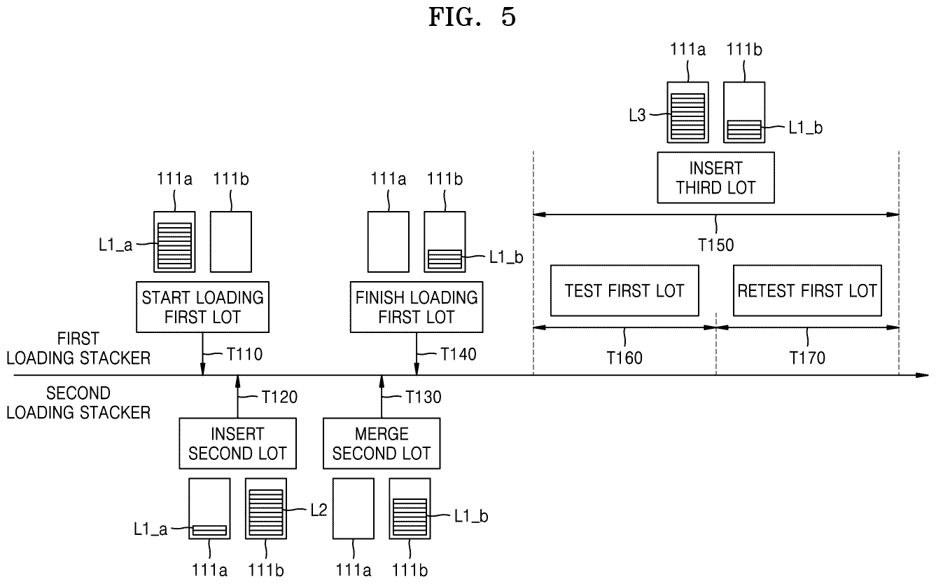

The loading stacker 111 may accommodate one or more semiconductor chips separated in units of lots and may provide the loading unit 120 with the semiconductor chips organized by lot, but is not limited thereto. After the semiconductor chips in one lot unit are tested, the semiconductor chips in the next lot may be tested. In this case, in the initial stage, a first lot (e.g., L1_a, see FIG. 5) may be accommodated (e.g., loaded onto, provided, etc.) in the first loading stacker 111a, and a second lot (e.g., L2, see FIG. 5) may be accommodated in the second loading stacker 111b, etc.

The loading unit 120 may receive the customer tray including untested semiconductor chips from the loading stacker 111, and may load the untested semiconductor chips onto a test tray 125 waiting on the loading unit 120. In addition, the loading unit 120 may receive semiconductor chips classified as defective based on test results from the unloading stacker 113, and may load the defective semiconductor chip onto the test tray 125 waiting on the loading unit 120.

A loading set plate 121 may provide a space where a customer tray may be mounted, wherein the semiconductor chips to be tested are stacked on the customer tray. That is, the customer tray, on which the untested semiconductor chips are stacked, may be transferred from the loading stacker 111 and mounted on the loading set plate 121. In addition, a customer tray on which defective semiconductor chips are stacked (e.g., semiconductor chips which were previously determined to be defective and/or unsellable, etc.) may be transferred from the first unloading stacker 113a and may be mounted on the loading set plate 121. Untested semiconductor chips and primary defective semiconductor chips (e.g., semiconductor chips which have been tested once and/or need further testing, a preliminary defective chip, etc.) may wait on the loading set plate 121 before being loaded onto the test tray 125.

Semiconductor chips located on the upper portion of the loading set plate 121 may be transferred to the test tray 125 by a loading robot (e.g., loading machinery, a loading apparatus, an automated loading apparatus, etc.) included in the loading unit 120, but the example embodiments are not limited thereto. In this case, the loading robot may include an absorption medium (e.g., a receiving medium, a receiving surface, a receiving tray, etc.) on a surface facing the semiconductor chips, but is not limited thereto. The loading robot may absorb and/or receive the semiconductor chips located on the loading set plate 121, and may transfer the semiconductor chips from the loading set plate 121 to the test tray 125.

The test tray 125 may include a plurality of accommodation portions (e.g., accommodation spaces, locations, etc.) in which semiconductor chips may be accommodated, stored, placed, and/or loaded, and the semiconductor chips loaded onto the test tray 125 may be sequentially filled from the upper portion of the test tray 125 to the lower portion of the test tray 125, but is not limited thereto. For example, the test tray 125 may include accommodation portions arranged in n rows and m columns, allowing n×m semiconductor chips to be stacked on one test tray 125, but is not limited thereto. At least two test trays 125 may be used for testing, and in this case, the loading capacity of the test tray 125 is the product of the loading capacity of a single test tray 125 multiplied by the number of test trays 125 used for testing. For example, when tests in a single test cycle are conducted using two test trays 125, the loading capacity of the test tray 125 is 2×n×m.

The test tray 125 may sequentially circulate around the loading unit 120, the test unit 130, and the unloading unit 140. The loading unit 120 may insert the test tray 125, which includes semiconductor chips to be tested, into the test unit 130, the test unit 130 may test the semiconductor chips stacked on the test tray 125 and may move the test tray 125 to the unloading unit 140, and the unloading unit 140 may unload the tested semiconductor chips from the test tray 125 and load the empty test tray 125 back onto the loading unit 120. The test tray 125 moved to the loading unit 120 may wait on the loading unit 120 for the semiconductor chips to be tested next.

The test unit 130 may test the semiconductor chips stacked on the test tray 125 and move the test tray 125 to the unloading unit 140. The test unit 130 may include a soak chamber 131, a test chamber 133, and/or a desoak chamber 135, etc., but is not limited thereto.

Semiconductor chips to be tested may be transferred to the soak chamber 131 before being transferred to the test chamber 133, and the soak chamber 131 may heat or cool the semiconductor chips from room temperature to the test temperature desired and/or required in the test chamber 133. In this case, as the temperatures of the semiconductor chips are changed to the desired test temperature while in the soak chamber 131, the time taken to test the semiconductor chips may be shortened in comparison to the case where the temperatures of the semiconductor chips are changed to the desired test temperature in the test chamber 133 for testing of the semiconductor chips.

The semiconductor chips in the soak chamber 131 may be stacked on the test tray 125 and transferred to the test chamber 133. The test chamber 133 may test the electrical characteristics of the semiconductor chips and determine whether the tested semiconductor chips are defective or not. The semiconductor chips tested in the test chamber 133 may be transferred to the desoak chamber 135 while being stacked on the test chamber 125. The desoak chamber 135 may return the temperatures of the semiconductor chips, which are set to the test temperature, back to room temperature, thus removing thermal stress from the semiconductor chips.

However, the process of heating or cooling the semiconductor chips may not be desired and/or required before testing, and thus, the test unit 130 may not include (e.g., may omit) the soak chamber 131 and/or the desoak chamber 133 unlike the illustration of FIG. 1.

The unloading unit 140 may unload the semiconductor chips stacked on the test tray 125 extracted from the test unit 130. The unloading unit 140 may include a classifying unit 147 for classifying the tested semiconductor chips based on the test results and separating the tested semiconductor chips determined to be defective semiconductor chips (e.g., the semiconductor chips which have failed the test performed by the test unit 130) and the tested semiconductor chips determined to be good semiconductor chips (e.g., the semiconductor chips which have passed the test performed by the test unit 130), and an unloading set plate 141 on which a customer tray holding the semiconductor chips classified by the classifying unit 147, may be mounted, but the example embodiments are not limited thereto.

The classifying unit 147 may classify the semiconductor chips stacked on the test tray 125, which was extracted from the test unit 130, into primary defective semiconductor chips, secondary defective semiconductor chips, and good semiconductor chips based on the test results, wherein the primary defective semiconductor chips (e.g., preliminary defective semiconductor chips, etc.) have been determined to be defective during a first test, and the secondary defective semiconductor chips (e.g., confirmed defective semiconductor chips, etc.)_have been determined to be defective two or more times (e.g., has been determined to be defective in two or more tests). In other words, if a semiconductor chip has been determined to be defective during a first test, it is retested at least once more in order to confirm that the semiconductor chip is defective. The unloading unit 140 may use an unloading robot including an absorption medium to transfer the semiconductor chips, which are classified as above, to the unloading set plate 141. For example, the classifying unit 147 may transmit instructions to the unloading robot indicating which tested semiconductor chips are primary defective semiconductor chips, secondary defective semiconductor chips, and/or good semiconductor chips, and may transmit instructions causing the unloading robot to transfer the tested semiconductor chips to the unloading set plate 141 based on their classifications.

The unloading set plate 141 may provide a space where the customer tray including the tested semiconductor chips may be mounted, and may include a first unloading set plate 141a and a second unloading set plate 141b, etc., but is not limited thereto. The defective semiconductor chips may be stacked on the customer tray provided on the upper portion of the first unloading set plate 141a, and the good semiconductor chips may be stacked on the customer tray provided on the upper portion of the second unloading set plate 141b, but the example embodiments are not limited thereto.

The controller 150 may include a retest controller 151 and/or a lot controller 153, etc., but is not limited thereto. The retest controller 151 may transfer the defective semiconductor chips to the first unloading stacker 113a and the good semiconductor chips to the second unloading stacker 113b. The good semiconductor chips may be stacked on the customer tray and transferred to a location where a subsequent process after the testing process is performed. According to some example embodiments, one or more of the controller 150, the retest controller 151, and/or the lot controller 153, etc., may be implemented as processing circuitry. Processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

The retest controller 151 may allow and/or cause the defective semiconductor chips to be directly transferred to (e.g., directly loaded onto) the loading set plate 121 from the first unloading stacker 113a. The retest controller 151 may be configured to detect whether the loading set plate 121 is empty, for example, based on sensor data obtained from at least one sensor (not shown) and to transmit instructions to at least one robot based on the detection results, thereby enabling and/or causing the transfer of the defective semiconductor chips to the loading set plate 121 by the at least one robot and to enable and/or cause the transfer of the defective semiconductor chips from the first unloading stacker 113a to the loading set plate 121 by the at least one robot.

Compared to the case where defective semiconductor chips are transferred and stored in the first loading stacker 111a and then moved again to the loading set plate 121, processes desired and/or required for such transfers may be reduced, and thus, the process time for testing may be shortened. The retest controller 151 may determine whether to transfer the defective semiconductor chips from the first unloading stacker 113a to the loading set plate 121 and enable the transfer of the defective semiconductor chips at an appropriate time.

The lot controller 153 may control a lot transfer robot (not shown) to insert lots into the first loading stacker 111a and/or the second loading stacker 111b, etc.

For example, the controller 150 may include a memory device such as read only memory (ROM) or random access memory (RAM), at least one processor, for example, a microprocessor, a central processing unit (CPU), a graphics processing unit (GPU), and/or the like, which may be configured to perform special purpose arithmetic operation(s), special purpose algorithms, and/or special purpose computer readable instructions in order to perform the operations of the methods disclosed herein. For example, the controller 150 may control one or more robots to perform physical actions, such as the loading and/or unloading of semiconductor chips onto various platforms discussed below. Additionally, while the following description discusses the retest controller 150 and the lot controller 153 as separate components, the example embodiments are not limited thereto, and for example, the controller 150 may perform the functionality of both the retest controller 150 and the lot controller 153, etc. Further, while various physical operations of the methods discussed below are described as being performed by a robot, the example embodiments are not limited thereto, and for example, in some example embodiments, a person may perform one or more of the physical operations based on instructions sent to, displayed to, etc., the person by the controller, etc.

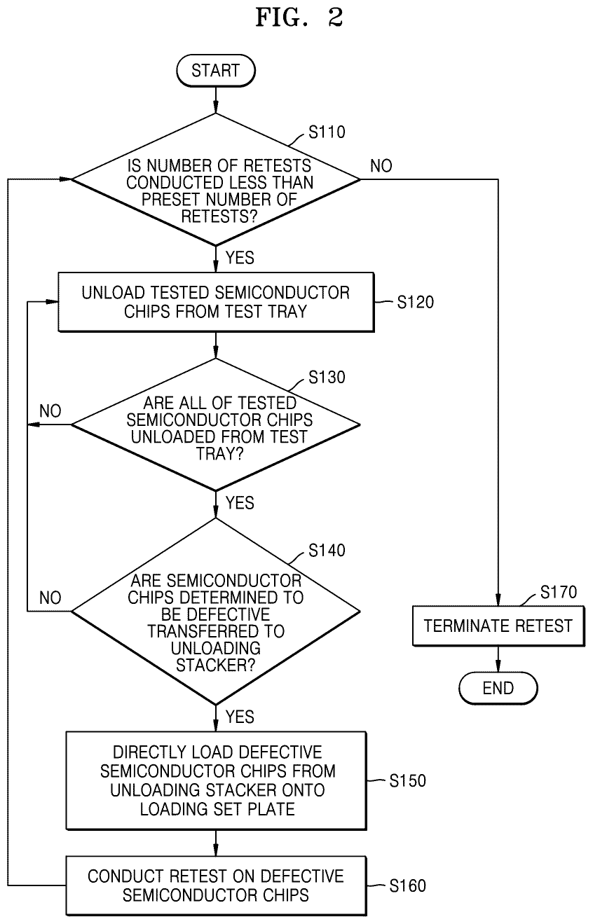

FIG. 2 is a flowchart illustrating the operation of the retest controller (151, see FIG. 1), according to at least one example embodiment.

Referring to FIGS. 1 and 2, in operation S110, the retest controller 151 determines whether the number of retests conducted is less than the desired and/or preset number of retests (e.g., a retest threshold value, etc.). Here, the expression “the desired and/or preset number of retests” refers to the number of times semiconductor chips determined to be defective have been tested while the test unit 130 tests untested semiconductor chips (e.g., the testing process). Therefore, the retest process may continue until all semiconductor chips determined to be defective have undergone retesting until the desired and/or preset number of retests have been performed. Then, when the number of retests conducted is the same as the desired and/or preset number of retests (e.g., the number of retests conducted reaches the retest threshold value), the retest controller 151 considers that the retest has been conducted on all of the semiconductor chips determined to be defective, and the retest process is terminated in operation S170.

Then, in operation S120, the semiconductor chips, which are stacked on the test tray 125 and tested by the test unit 130, may be unloaded from the test tray 125 by at least one robot in response to at least one instruction from the retest controller 151. The tested semiconductor chips may be unloaded from the test tray 125 by the at least one robot in response to at least one instruction from the retest controller 151, and based on the test results, the tested semiconductor chips may be classified by the classifying unit 147 into defective semiconductor chips and good semiconductor chips.

Then, in operation S130, the retest controller 151 determines that all of the tested semiconductor chips are unloaded from the test tray 125 based on sensor readings associated with the test tray 125, etc. When all of the semiconductor chips stacked on the test tray 125 are unloaded based on the result of determining, the test tray 125 may be transferred to the loading unit 120 by the at least one robot in response to at least one instruction from the retest controller 151 and may wait to load the next batch of semiconductor chips scheduled to be tested next. The classified semiconductor chips may be transferred to the first unloading set plate 141a and the second unloading set plate 141b by the at least one robot in response to at least one instruction from the retest controller 151. Then, the unloading unit 140 may transfer defective semiconductor chips, which wait on the first unloading set plate 141a, to the first unloading stacker 113a, and good semiconductor chips, which wait on the second unloading set plate 141b, to the second unloading stacker 113b.

Then, the retest controller 151 determines in operation S140 that the defective semiconductor chips have been transferred to the first unloading stacker 113a based on sensor readings associated with the first unloading stacker. Based on the result of determining, when the defective semiconductor chips are transferred to the first unloading stacker 113a, the retest controller 150 may cause and/or instruct at least one robot to directly load the defective semiconductor chips from the first unloading stacker 113a onto the loading set plate 121 in operation S150.

When one or more of the tested semiconductor chips are not unloaded and remain on the test tray 125 in operation S130, operation S120 is performed again by the retest controller 151 so that the tested semiconductor chips are unloaded from the test tray 125 by the at least one robot in response to at least one instruction from the retest controller 151. After completing the unloading process on the test tray 125, the retest controller 151 determines whether there are any defective semiconductor chips that are still loaded in the test tray (e.g., operation S130 is performed again). In addition, when no defective semiconductor chips are transferred to the first unloading stacker 113a in operation S140, no remaining defective semiconductor chips exist at this point in time, and thus, the retest controller 151 may not causing the directly loading of the defective semiconductor chips onto the loading set plate 121 (e.g., may skip operation S150).

When all of the defective semiconductor chips are loaded onto the loading set plate 121, the defective semiconductor chips may be transferred to the test unit 130 and retested in operation S160. Once the retest has been performed by the test unit 130, the retest controller 151 may increment the number of retests performed and may return to operation S110.

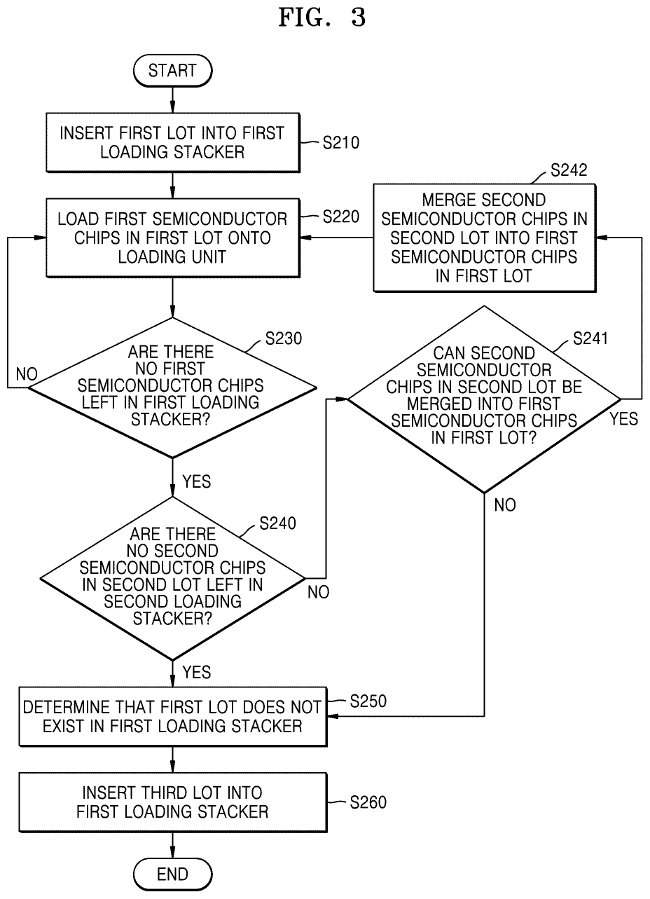

FIG. 3 is a flowchart illustrating a semiconductor test method using the semiconductor test apparatus (10, see FIG. 1), according to at least one example embodiment.

Hereinafter, referring to FIGS. 1 and 3, the semiconductor test method according to at least one example embodiment may include operation S210 wherein the lot controller 153 may cause, instruct, and/or enable a robot to insert a first lot (e.g., L1_a, see FIG. 5) into the first loading stacker 111a. Here, the first lot (e.g., L1_a, see FIG. 5) may be a collection unit of semiconductor chips, and for example, 25 semiconductor chips may be defined as one lot. However, this is only an example, and the number of semiconductor chips forming one lot is not limited to 25. The lot controller 153 may cause, instruct, and/or enable the robot to insert the first lot (e.g., L1_a, see FIG. 5), located outside the semiconductor test apparatus 10, into the first loading stacker 111a in the tray housing unit 110. The first lot L1_a, a second lot L2, and a third lot L3 are described below by referring to FIG. 5 together, but the example embodiments are not limited thereto.

The semiconductor test method according to at least one example embodiment may include operation S220 wherein the lot controller 153 controls the first loading stacker 111a to load the first semiconductor chips in the first lot L1_a onto a loading unit. In this case, the first semiconductor chips may be semiconductor chips on which a semiconductor test has not been conducted. For example, the lot controller 153 may control the first loading stacker 111a to load, onto the loading unit 120, the first semiconductor chips stored in the first lot L1_a one by one, but the example embodiments are not limited thereto. The first semiconductor chips may be stacked on a customer tray by the loading unit 120 and transferred to the loading set plate 121.

Then, the semiconductor test method according to at least one example embodiment may include operation S230 wherein the lot controller 153 determines whether the first semiconductor chips exist in the first loading stacker 111a (e.g., determine whether first semiconductor chips remain on the first loading stacker 111a, etc.). In this case, when the first semiconductor chips remain inside the first loading stacker 111a, the method returns to operation S220, otherwise the method proceeds to operation S240.

The semiconductor test method according to at least one example embodiment may include operation S240 wherein the lot controller 153 may determine whether second semiconductor chips in the second lot (e.g., L2, see FIG. 5) exist in the second loading stacker 111b (e.g., determine whether second semiconductor chips remain on the second loading stacker 111b, etc.). Similar to the first lot L1_a, the second lot (e.g., L2, see FIG. 5) may also be a collection unit of semiconductor chips and may be substantially the same as the first lot L1_a stored in the first loading stacker 111a except that the second lot L2 is stored in the second loading stacker 111b.

The semiconductor test method according to at least one example embodiment may include operation S250 wherein, in response to no second semiconductor chips in the second lot being left in the second loading stacker 111b, the lot controller 153 may determine that the first lot L1_a does not exist in the first loading stacker 111a, etc. In this case, the lot controller 153 determines that none of the first semiconductor chips forming the first lot L1_a are present and the first loading stacker 111a is designated as an empty stacker. The first loading stacker 111a designated as the empty stacker transitions to a state in which an additional lot may be inserted from the outside (e.g., an external source, etc.).

The semiconductor test method according to at least one example embodiment may include operation S260 wherein the lot controller 153 may cause, enable, and/or instruct a robot to insert the third lot L3 into the first loading stacker 111a. When the first loading stacker 111a is designated as the empty stacker, the lot controller 153 may be configured to cause, enable, and/or instruct the robot to provide the third lot L3 to the first loading stacker 111a. The third lot L3 may be a unit of semiconductor chips that is distinct from the first lot L1_a or the second lot L2. When all of the untested semiconductor chips (e.g., the first semiconductor chips in the first lot L1_a) are located on the loading set plate 121, the lot controller 153 may be configured to provide a new third lot L3 to the first loading stacker 111a. The third semiconductor chips forming the third lot L3 are untested semiconductor chips and become the test targets after the test conducted on the second semiconductor chips forming the second lot L2 is completed.

Returning to operation S240, in response to one or more second semiconductor chips of the second lot remaining in the second loading stacker 111b, the lot controller 153 proceeds to operation S241 and determines whether second semiconductor chips in the second lot be merged into (e.g., added to) the first semiconductor chips in the first lot. If the second semiconductor chips cannot be merged into the first lot, the method proceeds to operation S250. If the second semiconductor chips can be merged into the first lot (e.g., there is enough space in the first lot to accommodate the remaining second semiconductor chips, etc.), in operation S242, the lot controller 153 causes, enables, and/or instructs the robot to merge the second semiconductor chips of the second lot with the first semiconductor chips in the first lot.

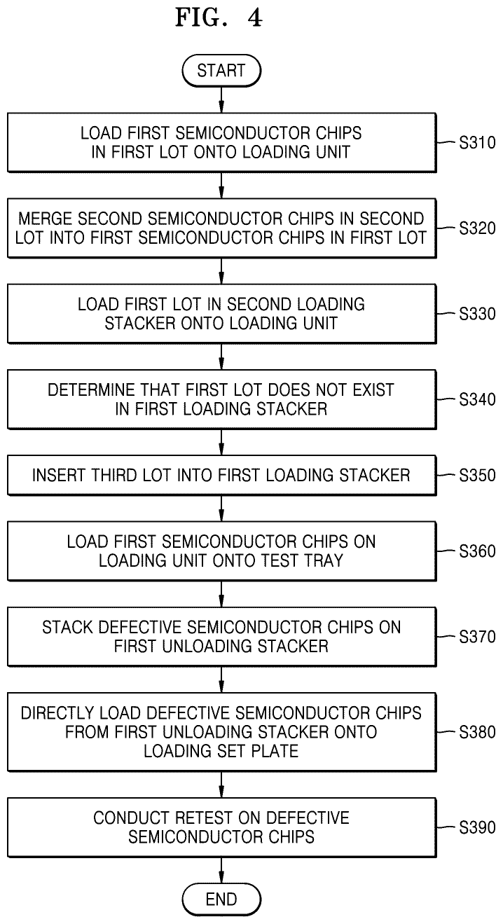

FIG. 4 is a flowchart illustrating a semiconductor test method using the semiconductor test apparatus 10, according to at least one example embodiment. The semiconductor test method of FIG. 4 is a semiconductor test method including merging the second lot (e.g., L2, see FIG. 5) loaded in the second loading stacker 111b into the first lot (e.g., L1_a, see FIG. 5). FIG. 5 is a flowchart illustrating a semiconductor test method using the semiconductor test apparatus (10, see FIG. 1), according to at least one example embodiment.

In particular, FIG. 5 is a chronological flowchart illustrating the semiconductor test method of FIG. 4, and based on the arrow following the time sequence of FIG. 5, the upper part indicates events occurring based on the first loading stacker 111a and the lower part indicates events occurring based on the second loading stacker 111b.

Referring to FIGS. 1, 4, and 5, the semiconductor test method may include operation S310 of loading the first semiconductor chips in the first lot L1_a onto the loading unit 120 by at least one robot in response to at least one instruction from a controller, e.g., the controller 150, etc. As shown in FIG. 5, at T110, when the first semiconductor chips in the first loading stacker 111a start being loaded onto the loading unit 120, the first semiconductor chips in the first lot L1_a remaining in the first loading stacker 111a correspondingly decrease. While the first semiconductor chips in the first loading stacker 111a are loaded onto the loading unit 120, the second lot L2 may be introduced by the at least one robot in response to at least one instruction from the controller 150 into the second loading stacker 111b at T120 and may include untested semiconductor chips, similar to the first lot L1_a, etc.

Then, the semiconductor test method may include operation S320 of merging the second semiconductor chips in the second lot L2 into the first semiconductor chips in the first lot L1_a(e.g., adding and/or combining the second semiconductor chips of the second lot L2 to the first lot L1_a, etc.) by the at least one robot in response to at least one instruction from the controller 150. The merging of the second semiconductor chips in the second lot L2 proceeds after the existing first lot L1_a stored in the first loading stacker 111a is entirely and/or completely loaded onto the loading unit 120. When the second semiconductor chips in the second lot L2 are merged into the first semiconductor chips in the first lot L1_a, the second semiconductor chips in the second lot L2 are defined as first semiconductor chips in a first lot L1_b from that moment onwards. Therefore, after the above merging, the lot remaining in the second loading stacker 111b is defined as the first lot L1_b.

According to at least one example embodiment, the semiconductor test method may include operation S330 of continuing to load the first lot L1_b stored in the second loading stacker 111b onto the loading unit 120 after the second lot L2 is merged into the first lot L1_b by the at least one robot in response to at least one instruction from the controller 150. In addition, after the originally targeted number of semiconductor chips have been loaded onto the loading unit 120, the loading of the first lot L1_b is completed at T140. In this case, the first lot L1_b may remain in the second loading stacker 111b in some cases.

Then, the semiconductor test method may include operation S340 of determining by the controller 150 based on sensor readings that the first lot L1_a does not exist in the first loading stacker 111a (e.g., there are no remaining first semiconductor chips from the first lot L1_a on the first loading stacker 111a, etc.). When is the controller 150 determines that the first lot L1_a does not exist in the first loading stacker 111a, the first loading stacker 111a is designated as an empty stacker. The first loading stacker 111a designated as the empty stacker transitions to a state in which an additional lot may be received from the outside.

According to at least one example embodiment, the semiconductor test method may include operation S350 of inserting the third lot L3 into the first loading stacker 111a. For example, the lot controller 153 may instruct at least one robot to insert the third lot L3 into the first loading stacker 111a after the first lot L1_a has been completely loaded onto the loading unit 120. In this case, according to at least one example embodiment, a point in time when the third lot L3 is inserted into the first loading stacker 111a may be immediately after the first lot L1_a in the first loading stacker 111a is completely loaded onto the loading unit 120, but the example embodiments are not limited thereto.

The lot controller 153 may be configured to instruct at least one robot to provide and/or transfer the third lot L3 to the first loading stacker 111a when the first semiconductor chips in the first lot L1_a are located on the loading set plate 121. In addition, the lot controller 153 may be configured to instruct the at least one robot to provide the third lot L3 to the first loading stacker 111a while the first semiconductor chips in the first lot L1_a are tested by the test unit 130. Also, the lot controller 153 may be configured to instruct the at least one robot to provide the third lot L3 to the first loading stacker 111a while semiconductor chips determined to be defective among the first semiconductor chips in the first lot L1_a are retested by the test unit 130.

Then, the test unit 130 of the semiconductor test apparatus 10 may proceed with the semiconductor test on the first semiconductor chips in the first lots L1_a and L1_b. The first lots L1_a and L1_b may include the first lot L1_a stored in the first loading stacker 111a and the first lot L1_b merged with the second lot L2 stored in the second loading stacker 111b, etc. According to at least one example embodiment, the semiconductor test method may include operation S360 of loading the first semiconductor chips in the loading unit 120 onto the test tray 125. The first semiconductor chips may be loaded onto the test tray 125 waiting on the loading unit 120 by the at least one robot in response to at least one instruction from the controller 150. In this case, before being loaded onto the test tray 125, the first semiconductor chips may wait on the loading set plate 121 of the loading unit 120. The loading unit 120 may be configured such that the test tray 125, on which the first semiconductor chips to be tested are stacked, may be inserted into the test unit 130, and the test unit 130 may test the first semiconductor chips stacked on the test tray 125. The tested first semiconductor chips are classified into defective semiconductor chips and good semiconductor chips based on results of at least one semiconductor test performed by the test unit 130. For example, the test unit 130 may perform electrical characteristic tests on the first semiconductor chips to determine whether the tested first semiconductor chips perform as desired and/or expected based on an electrical characteristic threshold, perform logical tests on the first semiconductor chips to determine whether the tested first semiconductor chips perform logical operations as desired and/or expected based on a logical performance threshold, etc., but the example embodiments are not limited thereto.

Then, according to at least one example embodiment, the semiconductor test method may include operation S370 of loading the semiconductor chips determined to be defective onto the first unloading stacker 113a by the at least one robot in response to at least one instruction from the controller 150. Similar to the loading stacker 111, the first unloading stacker 113a may provide a space and/or accommodations where the semiconductor chips of the lot are loaded, the semiconductor chips determined to be defective are stacked on the first unloading stacker 113a, and the semiconductor chips determined to be of good quality are stacked on the second unloading stacker 113b, but the example embodiments are not limited thereto.

Then, the semiconductor test method may include operation S380 of loading and/or directly loading the defective semiconductor chips from the first unloading stacker 113a to the loading set plate 121 by the at least one robot in response to at least one instruction from the controller 150. As the defective semiconductor chips are transferred and/or directly transferred to the loading set plate 121 instead of the first loading stacker 111a, a new third lot L3 may be inserted into the first loading stacker 111a which is empty by the at least one robot in response to at least one instruction from the controller 150. Therefore, as the third lot L3 is quickly inserted into the first loading stacker 111a, the semiconductor test apparatus 10 may reduce the waiting time taken to insert, into the loading stacker 111, the lot subject to be testing, which results in the decrease in the total test time.

Then, the semiconductor test method may include operation S390 of retesting the defective semiconductor chips by the test unit 130. After the first test on the first semiconductor chips in the first lots L1_a and L1_b is completed, the semiconductor chips, which are classified as the defective semiconductor chips among the first semiconductor chips based on the test results, are retested by the test unit 130.

The defective semiconductor chips waiting on the loading set plate 121 may repeatedly undergo the testing process designed for untested semiconductor chips for a desired number of times by the test unit 130. In the loading set plate 121, the space in which the customer tray containing the defective semiconductor chips to be retested may be stably placed may be provided. Then, the at least one robot, e.g., the loading robot, based on instructions from the controller 150 (e.g., the lot controller 153, etc.), may absorb the defective semiconductor chips located on the loading set plate 121 and transfer the defective semiconductor chips from the loading set plate 121 to the test tray 125. The loading unit 120 may insert the test tray 125, on which defective semiconductor chips to be tested are stacked, into the test unit 130, and the test unit 130 may test again the defective semiconductor chips stacked on the test tray 125 and then move the defective semiconductor chips to the unloading unit 140. After retesting, the semiconductor chips which have been secondarily determined to be defective (e.g., confirmed to be defective, etc.), may either be finally classified as defective and discarded or may be subjected to additional testing to determine whether they are defective.

In addition, while the retesting is conducted on the defective semiconductor chips, the third lot L3 may be inserted into the second loading stacker 111b by the at least one robot in response to at least one instruction from the controller 150.

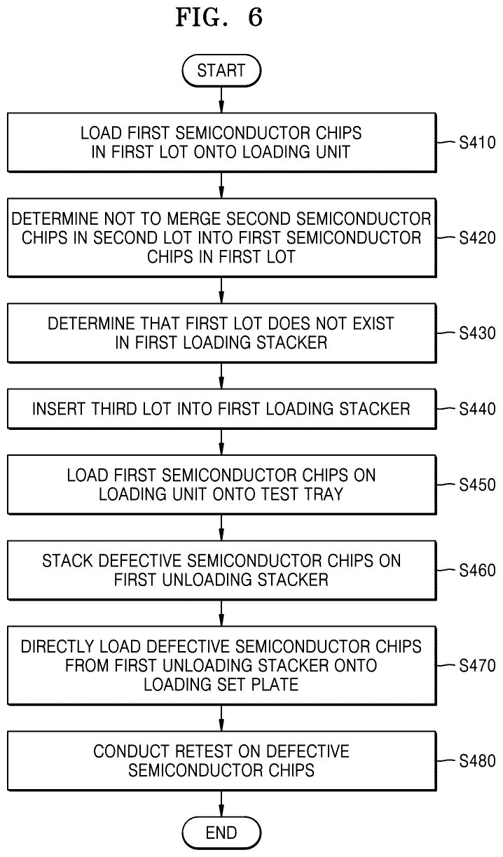

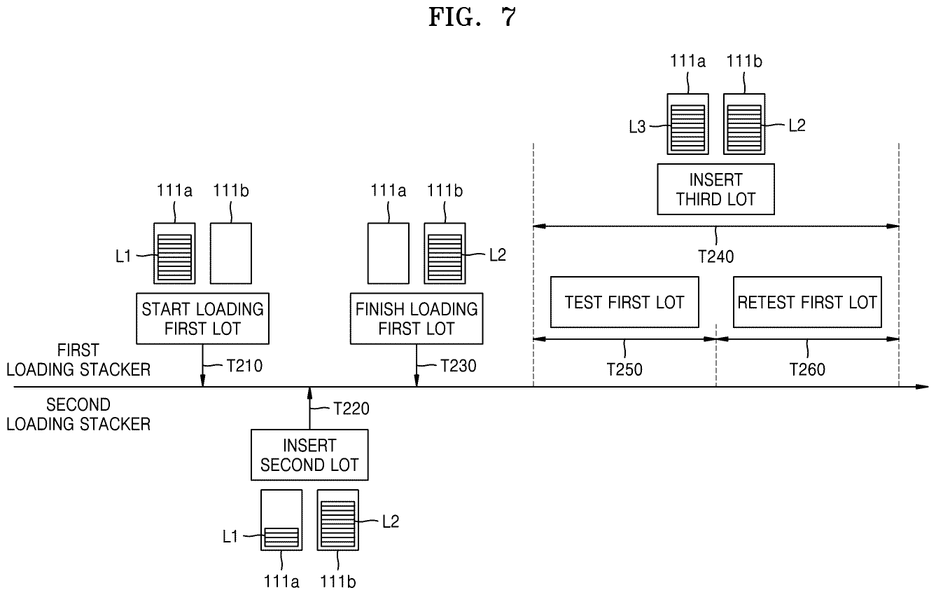

FIG. 6 is a flowchart illustrating a semiconductor test method using a semiconductor test apparatus, according to at least one example embodiment, and FIG. 7 is a flowchart illustrating a semiconductor test method using a semiconductor test apparatus, according to at least one example embodiment.

The semiconductor test method of FIGS. 6 and 7 is substantially the same as or similar to the semiconductor test method described with reference to FIGS. 4 and 5 except that the second semiconductor chips in the second lot L2 are not merged into the first semiconductor chips in a first lot L1. Therefore, processes corresponding to those included in the semiconductor test method of FIGS. 4 and 5 are not described or are simply described.

FIG. 7 is a chronological flowchart illustrating the semiconductor test method of FIG. 6, and based on the arrow following the time sequence of FIG. 7, the upper part indicates events occurring based on the first loading stacker 111a and the lower part indicates events occurring based on the second loading stacker 111b.

Referring to FIGS. 1, 6, and 7, the semiconductor test method may include operation S410 of loading the first semiconductor chips in the first lot L1_a onto the loading unit 120 by the at least one robot in response to at least one instruction from the controller 150. As shown in FIG. 7, when the first semiconductor chips in the first loading stacker 111a start being loaded onto the loading unit 120, the first semiconductor chips in the first lot L1 remaining in the first loading stacker 111a gradually decrease at T210, which is the same as those described with reference to FIGS. 4 and 5. While the first semiconductor chips in the first loading stacker 111a are loaded onto a loading unit 120, the second lot L2 may be inserted into the second loading stacker 111b at T220, but is not limited thereto.

According to at least one example embodiment, the semiconductor test method may include operation S420 of the controller 150 determining not to merge the second semiconductor chips in the second lot L2 into the first semiconductor chips in the first lot L1. As the second semiconductor chips in the second lot L2 stored in the second loading stacker 111b are not merged into the first semiconductor chips in the first lot L1, the semiconductor chips stacked in the second loading stacker 111b may remain defined as the second semiconductor chips in the second lot L2.

Then, after the first lot L1 in the first loading stacker 111a is completely loaded onto the loading unit 120 (e.g., no first semiconductor chips remain on the first loading stacker 111a), the semiconductor test method may include operation S430 of determining that the first lot L1 does not exist in the first loading stacker 111a by the controller 150 based on sensor readings associated with the first loading stacker 111a. The above operation is the same as operation S340 of FIG. 4 and thus is not specifically described.

Then, the semiconductor test method may include operation S440 of inserting the third lot L3 into the first loading stacker 111a by the at least one robot in response to at least one instruction from the controller 150. After the first lot L1 is entirely loaded onto the loading unit 120, the third lot L3 may be inserted into the first loading stacker 111a by the at least one robot in response to at least one instruction from the controller 150. In this case, according to at least one example embodiment, a point in time when the third lot L3 is inserted into the first loading stacker 111a may be immediately after the first lot L1_a is entirely loaded onto the loading unit 120, but the example embodiments are not limited thereto.

The lot controller 153 may be configured to instruct the at least one robot to provide the third lot L3 to the first loading stacker 111a while the first semiconductor chips in the first lot L1_a are tested by the test unit 130. Also, the lot controller 153 may be configured to instruct the at least one robot to provide the third lot L3 to the first loading stacker 111a while semiconductor chips determined to be defective among the first semiconductor chips in the first lot L1_a are retested by the test unit 130.

Then, the test unit 130 of the semiconductor test apparatus 10 may continue to perform the semiconductor test on the first semiconductor chips in the first lot L1 at T250. According to at least one example embodiment, the semiconductor test method may include operation S450 of loading the first semiconductor chips on the loading unit 120 onto the test tray 125 by the at least one robot in response to at least one instruction from the controller 150. The above operation is the same as operation S360 of FIG. 4 and thus is not specifically described.

Then, according to at least one example embodiment, the semiconductor test method may include operation S460 of loading the semiconductor chips determined to be defective onto the first unloading stacker 113a by the at least one robot in response to at least one instruction from the controller 150. The above operation is the same as operation S370 of FIG. 4 and thus is not specifically described.

Then, the semiconductor test method may include operation S470 of loading and/or directly loading the defective semiconductor chips from the first unloading stacker 113a to the loading set plate 121 by the at least one robot in response to at least one instruction from the controller 150. The above operation is the same as operation S380 of FIG. 4 and thus is not specifically described.

Then, the semiconductor test method may include operation S480 of retesting the defective semiconductor chips by the test unit 130. The above operation is the same as operation S390 of FIG. 4 and thus is not specifically described.

Consequently, according to the semiconductor test method according to at least one example embodiment, regardless of whether the second semiconductor chips in the second lot L2 are merged into the first semiconductor chips in the first lot L1, the third lot L3 may be inserted into the first loading stacker 111a immediately after the first lot L1 in the first loading stacker 111a is completely loaded onto the loading unit 120 by the at least one robot in response to at least one instruction from the controller 150, but the example embodiments are not limited thereto. If the defective semiconductor chips are not directly transferred to the loading set plate 121 but to the loading stacker 111 again, the third lot L3 may not be inserted into the first loading stacker 111a until the retest on the defective semiconductor chips is completed, and thus, the semiconductor test may be delayed.

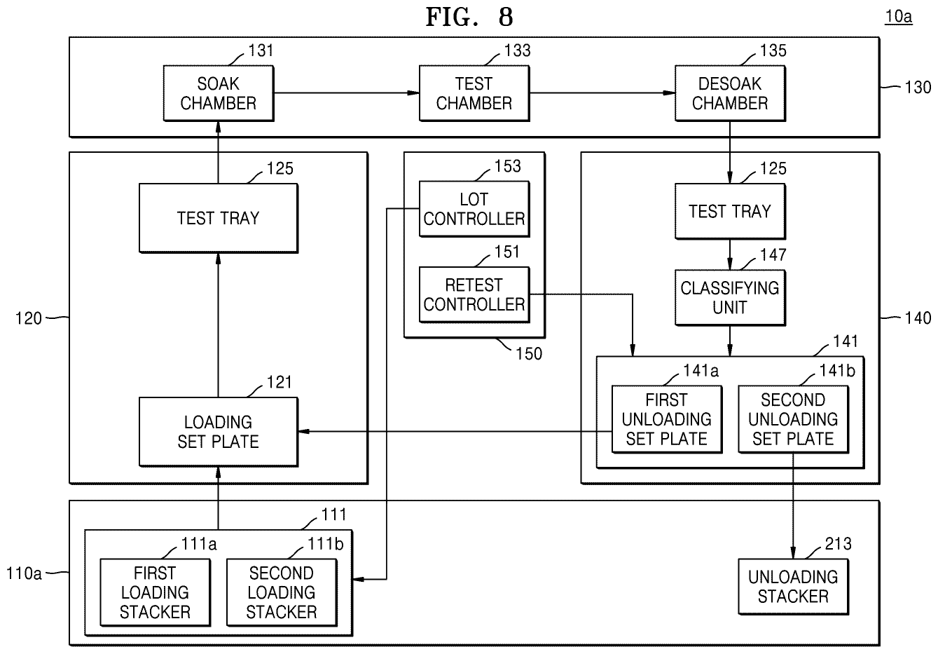

FIG. 8 is a block diagram of a semiconductor test apparatus 10a according to at least one example embodiment. The difference between the block diagram showing the semiconductor test apparatus 10a of FIG. 8 and the block diagram showing the semiconductor test apparatus 10 of FIG. 1 is mainly described.

Referring to FIG. 8, a tray housing unit 110a of the semiconductor test apparatus 10a may include one unloading stacker 213, but is not limited thereto. The semiconductor test apparatus 10 of FIG. 1 includes the unloading stacker 113 on which the semiconductor chips determined to be defective based on the semiconductor test results are stacked, while the tray housing unit 110a of the semiconductor test apparatus 10a of FIG. 8 does not include an unloading stacker on which defective semiconductor chips are stacked.

A customer tray, on which the defective semiconductor chips are stacked, may be transferred from the first unloading set plate 141a by the at least one robot in response to at least one instruction from the controller 150, and may be mounted on the loading set plate 121. The defective semiconductor chips mounted on the loading set plate 121 may wait on the loading set plate 121 before being loaded onto the test tray 125.

According to at least one example embodiment, as the retest controller 151 operates, the defective semiconductor chips are transferred from the first unloading set plate 141a to the loading set plate 121 at an appropriate and/or desired time. The retest controller 151 may allow, instruct, and/or cause the retest to be performed on the defective semiconductor chips by the test unit 130 and allow, instruct, and/or cause at least one robot to transfer the good semiconductor chips from a second unloading set plate 141b to the tray housing unit 110a. The good semiconductor chips may be stacked on the customer tray and may be transferred to a location where a subsequent process after the testing process is performed.

The retest controller 151 may allow, instruct, and/or cause at least one robot to transfer and/or directly transfer the defective semiconductor chips from the first unloading set plate 141a to the loading set plate 121. Compared to the case where defective semiconductor chips are transferred from the first unloading set plate 141a to the loading set plate 121 and stored and then moved again to the loading set plate 121, processes desired and/or required for such transfers may be reduced, and thus, the process time for testing may be shortened. The retest controller 151 may determine whether to transfer the defective semiconductor chips from first unloading set plate 141a to the loading set plate 121 and enable, instruct, and/or cause the at least one robot to transfer the defective semiconductor chips at an appropriate and/or desired time.

Compared to the semiconductor test apparatus 10 of FIG. 1, the defective semiconductor chips are not stored in the unloading stacker 213, and thus, the tray housing unit 110a may only include the unloading stacker 213 in which only the good semiconductor chips are accommodated.

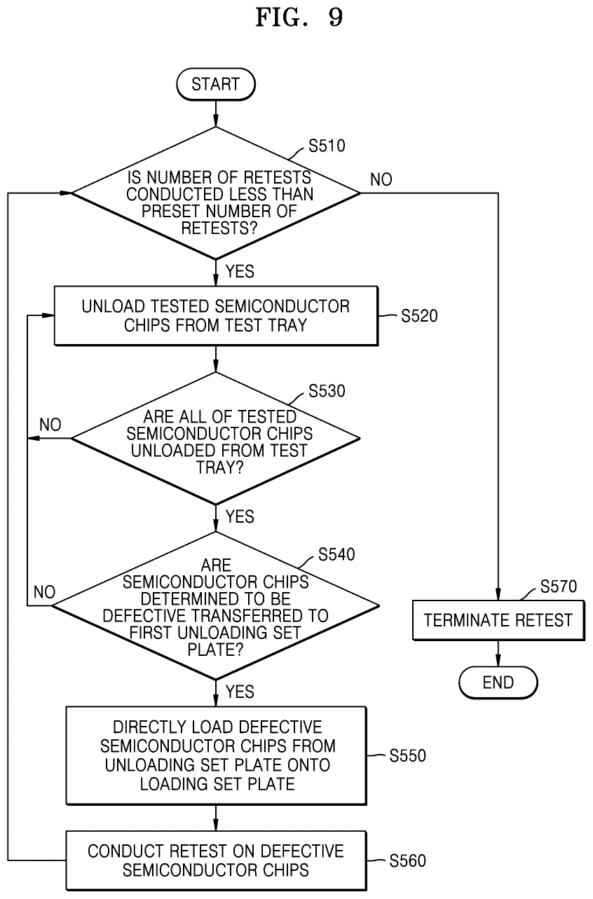

FIG. 9 is an example flowchart illustrating the operation of the retest controller 151, according to at least one example embodiment. The difference between the flowchart of FIG. 2 and the flowchart of FIG. 9 is mainly described, but the example embodiments are not limited thereto.

Referring to FIGS. 8 and 9, in operation S510, the retest controller 151 determines whether the number of retests conducted is less than the desired and/or preset number of retests. Then, when the number of retests conducted is equal to the desired and/or preset number of retests, is the retest controller 151 may determine that the retest has been conducted on all of the semiconductor chips determined to be defective, and the retest process is terminated in operation S570. Because operations are the same as operations S110 and S170 of FIG. 1, detailed descriptions thereof are omitted.

Then, in operation S520, the retest controller 151 may cause, enable, and/or instruct at least one robot to unload the semiconductor chips stacked on the test tray 125 and have been tested by the test unit 130, from the test tray 125. The above operation is the same as operation S120 of FIG. 1 and thus is not specifically described.

Then, in operation S530, the retest controller 151 may determine whether all of the tested semiconductor chips have been unloaded from the test tray 125. The above operation is the same as operation S130 of FIG. 1 and thus is not specifically described.

Then, the retest controller 151 may determine in operation S540 whether all of the defective semiconductor chips have been transferred to the first unloading set plate 141a based on sensor readings associated with the first unloading set plate 141a. Unlike operation S140 of FIG. 2, the semiconductor chips classified as defective are not transferred to the tray housing unit 110a via the first unloading set plate 141a by the at least one robot. When the defective semiconductor chips have been completely transferred to the first unloading set plate 141a based on the result of determining, the retest controller 150 may cause, enable, and/or instruct the at least one robot to load and/or directly load the defective semiconductor chips from the first unloading set plate 141a to the loading set plate 121, in operation S550.

When semiconductor chips are not unloaded and remain on the test tray 125 in operation S530, the retest controller 151 determines whether there are any defective semiconductor chips on the test tray 125 after the unloading process on the test tray 125 is completed based on sensor readings associated with the test tray 125. In addition, when no defective semiconductor chips are transferred to the first unloading set plate 141a in operation S540, the retest controller 151 determines no defective semiconductor chips exist at this point in time, and thus, the retest controller 151 may not cause, by the robot, the directly loading of the defective semiconductor chips to the loading set plate 121.

Then, when all of the defective semiconductor chips are loaded onto the loading set plate 121, the retest controller 151 may cause, instruct, and/or enable the defective semiconductor chips to be transferred to the test unit 130 by the robot and retested in operation S560.

While various example embodiments of the inventive concepts have been particularly shown and described, it will be understood that various changes in form and details may be made therein without departing from the spirit and scope of the following claims.

What is claimed is:

1. A semiconductor test apparatus comprising:
a tray housing including a loading stacker, a first unloading stacker, and a second unloading stacker, the loading stacker configured to receive a plurality of semiconductor chips for testing, the first unloading stacker configured to receive any defective semiconductor chips among the plurality of semiconductor chips, and the second unloading stacker configured to receive any good semiconductor chips among the plurality of semiconductor chips;
a loader configured to place, on a loading set plate, the plurality of semiconductor chips for testing, and load the plurality of semiconductor chips for testing onto a test tray;
a test device configured to test the plurality of semiconductor chips for testing stacked on the test tray;
an unloader configured to classify the plurality of tested semiconductor chips into the any defective semiconductor chip and the any good semiconductor chip based on results of the testing, place the any defective semiconductor chip on the first unloading stacker, and place the any good semiconductor chip onto the second unloading stacker; and
processing circuitry configured to,
cause at least one robot to transfer the any defective semiconductor chip from the first unloading stacker to the loading set plate,
cause the at least one robot to provide at least one additional semiconductor chip to the loading stacker, and
instruct the test device to retest the any defective semiconductor chip.

2. The semiconductor test apparatus of claim 1, wherein the processing circuitry is further configured to:
cause the at least one robot to transfer the any defective semiconductor chip to the loading set plate without passing through the first loading stacker.

3. The semiconductor test apparatus of claim 2, wherein the loader is further configured to:
load the any defective semiconductor chip onto the test tray from the loading set plate.

4. The semiconductor test apparatus of claim 1, wherein the processing circuitry is further configured to:
cause the at least one robot to provide the at least one additional semiconductor chip to the loading stacker in response to all of the plurality of semiconductor chips to be tested to be located on the loading set plate.

5. The semiconductor test apparatus of claim 1, wherein the processing circuitry is further configured to:
cause the at least one robot to provide the at least one additional semiconductor chip to the loading stacker while the plurality of semiconductor chips to be tested are tested by the test device.

6. The semiconductor test apparatus of claim 1, wherein the processing circuitry is configured to:
cause the at least one robot to provide the additional semiconductor chip to the loading stacker while the defective semiconductor chip is retested by the test device.

7. The semiconductor test apparatus of claim 1, wherein the loading stacker comprises:
a first loading stacker and a second loading stacker;
the first loading stacker configured to stack a first lot comprising a subset of the plurality of semiconductor chips to be tested; and
the second loading stacker configured to stack a second lot comprising a remaining subset of the plurality of semiconductor chips to be tested.

8. The semiconductor test apparatus of claim 1, wherein the test tray is configured to:
sequentially circulate between the loader, the test device, and the unloader.

9. The semiconductor test apparatus of claim 1, wherein the unloader comprises:
a first unloading set plate configured to receive the any defective semiconductor chip; and
a second unloading set plate configured to receive the any good semiconductor chip.

10. The semiconductor test apparatus of claim 1, wherein the test device comprises:
a soak chamber configured to preheat at least one semiconductor chip of the plurality of semiconductor chips to be tested;
a test chamber configured to conduct at least one test on the at least one preheated semiconductor chip; and
a desoak chamber configured to change a temperature of the at least one tested semiconductor chip to room temperature.

11. The semiconductor test apparatus of claim 1, wherein the processing circuitry is further configured to:
detect whether the loading set plate is empty; and
cause the at least one robot to transfer the any defective semiconductor chip from the first unloading stacker to the loading set plate in response to results of the detection.

12. The semiconductor test apparatus of claim 11, wherein the processing circuitry is further configured to:
start operating in response to the any defective semiconductor chip being transferred to the first unloading stacker; and
stop operating in response to the transfer of the any defective semiconductor chip from the first unloading stacker to the test tray being completed.

13. A semiconductor test apparatus comprising:
a tray housing including a first loading stacker and a second loading stacker, the first loading stacker configured to receive a first lot of semiconductor chips, and the second loading stacker configured to receive a second lot of semiconductor chips;
a loader configured to transfer the first lot from the tray housing to a loading set plate, and transfer the first lot from the loading set plate to a test tray;
a test device configured to test the semiconductor chips of the first lot on the test tray;
an unloader configured to classify the semiconductor chips of the first lot into any defective semiconductor chips among the semiconductor chips and any good semiconductor chips among the semiconductor chips based on results of the testing, transfer the any defective semiconductor chip to a first unloading set plate, and transfer the any good semiconductor chip to a second unloading set plate; and
processing circuitry configured to,
cause at least one robot to transfer the any defective semiconductor chip from the first unloading set plate to the loading set plate,
cause the at least one robot to transfer the any good semiconductor chip from the second unloading set plate to an unloading stacker,
cause the at least one robot to transfer an additional lot to the first loading stacker, and
instruct the test device to retest the any defective semiconductor chip on the loading set plate.

14. The semiconductor test apparatus of claim 13, wherein the processing circuitry is further configured to:
cause the at least one robot to transfer the any defective semiconductor chip to the loading set plate without passing through the first loading stacker.

15. The semiconductor test apparatus of claim 13, wherein the processing circuitry is further configured to:
cause the at least one robot to combine the second lot of semiconductor chips on the second loading stacker with the first lot of semiconductor chips on the first loading stacker.

16. The semiconductor test apparatus of claim 13, wherein the processing circuitry is further configured to:
cause the at least one robot to transfer the additional lot to the first loading stacker in response to the first lot of semiconductor chips being transferred to the loading set plate.

17. The semiconductor test apparatus of claim 13, wherein the processing circuitry is further configured to:
cause the at least one robot to transfer the additional lot to the first loading stacker while the first lot is tested by the test device.

18. The semiconductor test apparatus of claim 13, wherein the processing circuitry is further configured to:
cause the at least one robot to transfer the additional lot to the first loading stacker while the defective semiconductor chip is retested by the test device.

19. The semiconductor test apparatus of claim 13, wherein the first lot stacked on the first loading stacker and the second lot stacked on the second loading stacker each comprise a plurality of semiconductor chips to be tested.

20. A semiconductor test apparatus comprising:
a tray housing including a first loading stacker, a second loading stacker, a first unloading stacker, and a second unloading stacker, the first loading stacker configured to receive a first lot of semiconductor chips, the second loading stacker configured to receive a second lot of semiconductor chips, the first unloading stacker configured to receive any defective semiconductor chip among the first lot, and the second unloading stacker configured to receive any good semiconductor chip among the first lot;
a loader configured to transfer the first lot from the tray housing to a test tray;
a test device including a soak chamber, a test chamber, and a desoak chamber, the soak chamber configured to preheat the first lot, the test chamber configured to conduct a test on each of the semiconductor chips of the first lot, and the desoak chamber configured to change a temperature of the tested semiconductor chips of the first lot to room temperature;
an unloader configured to classify the semiconductors of the first lot into the any defective semiconductor chip and the any good semiconductor chip based on results of the testing, transfer the any defective semiconductor chip to the first unloading stacker, and transfer the any good semiconductor chip to the second unloading stacker; and
processing circuitry configured to,
cause at least one robot to transfer the any defective semiconductor chip to a loading set plate without passing through the loading stacker,
cause the at least one robot to transfer an additional semiconductor chip to the loading stacker, and
instruct the test device to retest the any defective semiconductor chip.
